(19) United States
(12) Patent Application Publication
(10) Pub. No.: US 2025/0322883 A1
(43) Pub. Date: Oct. 16, 2025

(54) LOW-LATENCY LOADING OF PADDING DATA ON MEMORY DIE

(71) Applicant: Micron Technology, Inc., Boise, ID (US)

(72) Inventors: Santhosh Kumar Siripragada, Rangareddy (IN); Yashwanth Kumar Grandhi, Hyderabad (IN)

(21) Appl. No.: 19/174,739

(22) Filed: Apr. 9, 2025

Related U.S. Application Data
(60) Provisional application No. 63/632,854, filed on Apr. 11, 2024.

(51) Int. Cl. G11C 16/10; G11C 16/08; G11C 16/34

(52) U.S. Cl. CPC G11C 16/102; G11C 16/08; G11C 16/3459

(57) ABSTRACT

Various embodiments provide for low-latency loading of padding data onto blocks of a memory circuit die, which can be used as part of a memory device of a memory system (e.g., a memory sub-system). According to some embodiments, padding data is transferred once into a data buffer component, such as a set of latches, a primary cache memory, a secondary cache memory, local memory, or the like of the memory circuit die. Then the transferred padding data is retained (in the data buffer component) and used to perform multiple programming operations (or program cycles) on multiple pages of multiple blocks. Additionally, for some embodiments, a program verification operation is skipped after one or more programming operations (or program cycles).

### PRIORITY APPLICATION

This application claims the benefit of priority to U.S. Provisional Application Ser. No. 63/632,854, filed Apr. 11, 2024, which is incorporated herein by reference in its entirety.

### TECHNICAL FIELD

Example embodiments of the disclosure relate generally to memory devices and, more specifically, to low-latency loading of padding data onto blocks of a memory circuit die, which can be used as part of a memory device of a memory system (e.g., a memory sub-system).

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 is a block diagram illustrating an example computing system that includes a memory sub-system, in accordance with some embodiments of the present disclosure.

FIGS. 2 through 4 illustrate flow diagrams of example methods for low-latency loading of padding data onto blocks of a memory circuit die, in accordance with some embodiments of the present disclosure.

FIG. 5 is a block diagram of an example computer system in which embodiments of the present disclosure may operate.

### DETAILED DESCRIPTION

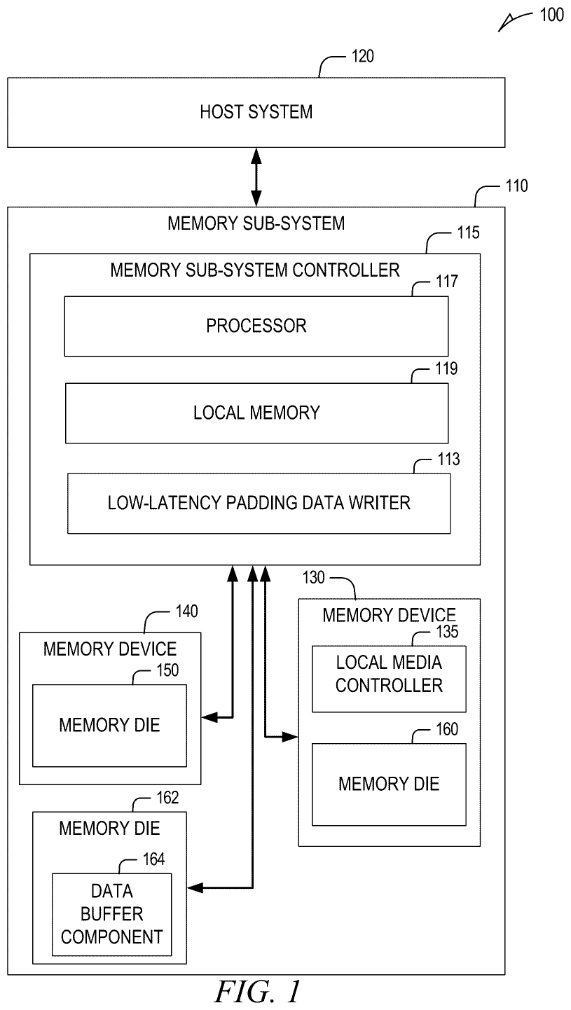

Aspects of the present disclosure are directed to low-latency loading of padding data onto blocks of a memory circuit die, which can be used as part of a memory device of a memory system (e.g., a memory sub-system). A memory sub-system can be a storage device, a memory module, or a hybrid of a storage device and memory module. Examples of storage devices and memory modules are described below in conjunction with FIG. 1. In general, a host system can utilize a memory sub-system that includes one or more components, such as memory devices that store data. The host system can send access requests to the memory sub-system, such as to store data at the memory sub-system and to read data from the memory sub-system.

The host system can send access requests (e.g., write commands, read commands) to the memory sub-system, such as to store data on a memory device at the memory sub-system, read data from the memory device on the memory sub-system, or write/read constructs with respect to a memory device on the memory sub-system. The data to be read or written, as specified by a host request (e.g., data access request or command request), is hereinafter referred to as “host data.” A host request can include logical address information (e.g., logical block address (LBA), namespace) for the host data, which is the location the host system associates with the host data. The logical address information (e.g., LBA, namespace) can be part of metadata for the host data. Metadata can also include error handling data (e.g., error-correcting code (ECC) codeword, parity code), data version (e.g., used to distinguish age of data written), valid bitmap (which LBAs or logical transfer units contain valid data), and so forth.

The memory sub-system can initiate media management operations, such as a write operation on host data that is stored on a memory device or a scan (e.g., media scan) of one or more blocks of a memory device. For example, firmware of the memory sub-system can re-write previously written host data from a location of a memory device to a new location as part of garbage collection management operations. The data that is re-written, for example as initiated by the firmware, is hereinafter referred to as “garbage collection data.”

“User data” hereinafter generally refers to host data and garbage collection data. “System data” hereinafter refers to data that is created and/or maintained by the memory sub-system for performing operations in response to host requests and for media management. Examples of system data include, and are not limited to, system tables (e.g., logical-to-physical memory address mapping table (also referred to herein as an L2P table), data from logging, scratch pad data, and so forth).

A memory device can be a non-volatile memory device. A non-volatile memory device is a package of one or more circuit die (or die). Each die (e.g., NAND-type memory device die) can comprise one or more physical planes (or planes). Groupings of planes can be organized according to logic units (LUNs), with each individual logic unit (LUN) being associated with a different grouping of planes. For some types of non-volatile memory devices (e.g., NOT-AND (NAND)-type devices), each plane comprises a set of physical blocks. For some memory devices, blocks are the smallest area that can be erased. Each block comprises a set of pages. Each page comprises a set of memory cells, which store bits of data. The memory devices can be raw memory devices (e.g., NAND), which are managed externally, for example, by an external controller. The memory devices can be managed memory devices (e.g., managed NAND), which are raw memory devices combined with a local embedded controller for memory management within the same memory device package.

Generally, writing data to such memory devices involves programming (by way of a program operation) the memory devices at the page level of a block, and erasing data from such memory devices involves erasing the memory devices at the block level (e.g., page level erasure of data is not possible). Certain memory devices, such as NAND-type memory devices, comprise one or more blocks, (e.g., multiple blocks) with each of those blocks comprising multiple pages, where each page comprises a subset of memory cells of the block, and where a single wordline of a block (which connects a group of memory cells of the block together) defines one or more pages of a block (depending on the type of memory cell). Depending on the embodiment, different blocks can comprise different types of memory cells. For instance, a block (a single-level cell (SLC) block) can comprise multiple SLCs, a block (a multi-level cell (MLC) block) can comprise multiple MLCs, a block (a triple-level cell (TLC) block) can comprise multiple TLCs, a block (a quad-level cell (QLC) block) can comprise QLCs, and a block (a penta-level cell (PLC) block) can comprise PLCs. Other blocks comprising other types of memory cells (e.g., higher-level memory cells, having higher bit storage-per-cell) are also possible.

Each worldline (of a block) can define one or more pages depending on the type of memory cells (of the block) connected to the wordline. For example, for an SLC block, a single wordline can define a single page. For an MLC block, a single wordline can define two pages-a lower page (LP) and an upper page (UP). For a TLC block, a single wordline can define three pages-a lower page (LP), an upper page (UP), and an extra page (XP). For a QLC block, a single wordline can define four pages-a lower page (LP), an upper page (UP), an extra page (XP), and a top page (TP) page. As used herein, a page of LP page type can be referred to as a “LP page,” a page of UP page type can be referred to as a “UP page,” a page of XP page type can be referred to as a “XP page,” and a page of TP page type can be referred to as a “TP page.” Each page type can represent a different level of a cell (e.g., QLC can have a first level for LPs, a second level for UPs, a third level for XPs, and a fourth level for TPs). To write data to a given page, a wordline associated with the given page is programmed according to a page programming algorithm (e.g., that causes one or more voltage pulses or pulses to memory cells of a block based on the memory). Generally, programming a single wordline of a block results all the pages in the single wordline being programmed, where the number pages being programmed depends on the type of block. For example, programming a single wordline of a QLC block usually results in four pages (e.g., LP, UP, XP, TP pages) associated with the single wordline being programmed.

The process of initializing blocks of a memory circuit die (e.g., NAND-type memory circuit die) after the memory device die is manufactured can improve the reliability and endurance of memory cells of those blocks. Traditionally, during the first power-up operation, blocks (e.g., SLC blocks, MLC blocks, TLC blocks, QLC blocks) of a memory circuit die (hereafter, memory die or memory chip) are assumed to be in an erased state and loaded/preloaded with padding data (e.g., dummy padding data), which can comprise a predetermined pattern of data. As part of the manufacturing process of a memory die, padding data can be loaded (e.g., preloaded) onto blocks of the memory die prior to the memory die (e.g., NAND-type memory die) being mounted, by way of a soldering process (e.g., an infrared soldering flow), onto a printed circuit board (PCB) with one or more other components to form or construct a memory device. Generally, the padding data loaded (e.g., preloaded) onto a block of a memory die can mitigate or assist in mitigating the thermal impact the soldering process has on the block, or the thermal impacts the block may experience while the memory die moves through a supply chain (e.g., during packaging, storage, or shipping of a memory system that includes a memory device comprising the memory die). Without the loaded (e.g., preloaded) data, blocks of a memory die can go bad due various thermal conditions (e.g., due to one or more thermal flows of a soldering process). The loading of padding data onto one or more blocks of a memory die often occurs during a power state awareness (PSA) process (e.g., stage or flow of manufacturing), where the current manufacturing state (e.g., non-soldering state, manufacturing flow state, pre-soldered state, soldered state) of the memory die is set and where data is written the memory die using one or more PSA trims.

Unfortunately, the conventional methodologies for loading padding data onto (e.g., writing padding data to) each block of a memory die can be quite write-intensive. In particular, conventional methodologies comprise performing the following for each individual wordline (e.g., each page) of each block of a memory die: transferring (e.g., from a memory system controller) padding data (e.g., pattern data) to the memory die to perform a programming operation (or program cycle) on the individual wordline, where the transferred padding data is stored in a data buffer component of the memory die, such a set of latches (e.g., one or more primary, secondary, or tertiary latches), a cache memory (e.g., primary data cache (PDC) or secondary data cache (SDC)), or local memory of the memory die; performing a programming operation (or programming cycle) on the individual wordline using the transferred padding data (e.g., from the set of latches, PDC, SDC, or local memory) to write the transferred padding data to one or more blocks of the memory die; and polling the individual wordline for programming operation/cycle completion (e.g., performing a program verification operation or cycle) before repeating the padding data transfer operation and programming operation/cycle for a next individual wordline. While this conventional method is effective in maintaining the integrity of the memory die, each step of the conventional method introduces significant latency to loading padding data to the memory die. As blocks of new memory die increase in data size/data capacity (e.g., with the development of newer technologies), so does the latency resulting from performing the conventional method to load padding data onto a memory die. This increase in latency (from performing the conventional method) can result in increased manufacturing time.

Various embodiments presented herein can cure these and other deficiencies of conventional methodologies for loading padding data onto (e.g., writing padding data to) each block of a memory die. In particular, various embodiments presented herein provide low-latency loading of padding data onto blocks of a memory circuit die, which can be used as part of a memory device of a memory system (e.g., a memory sub-system). According to some embodiments, padding data (e.g., comprising pattern data) is transferred (e.g., loaded) once into a data buffer component, such as a set of latches, a primary cache memory, a secondary cache memory, local memory, or the like of the memory die. Then, instead of retransferring padding data into the data buffer component for each program operation to be performed, the transferred padding data is retained in the data buffer component (whether a prior programming operation is successful or unsuccessful), and used to perform multiple programming operations (or program cycles) on multiple pages of multiple blocks. With the removal of extra transfer operations, the overall latency of performing a padding data load process can be reduced, and overall power usage can also be reduced. For some embodiments, a program verification operation (which is typically performed after a programming operation) is skipped after one or more programming operations (or program cycles), which can result in an additional reduction in latency of performing a padding data load process, and can result in an additional reduction in power usage by performing a padding data load process. Given that the padding data being programmed is generally non-meaningful data (e.g., dummy padding data), the skipping of program verification operations can be safely skipped without detrimental consequences. The skipping of program verification can be skipped even in instances where a programming failure is observed with respect to one or more block, as those one or more blocks can be retired during a different flow of the overall manufacturing process. For some embodiments, the programming operation performed is an SLC-block programming operation, which typically has a higher level of programming confidence and can permit the skipping of program verification operation after a programming operation.

During the loading of padding data onto one or more blocks of a memory circuit die, the use of various embodiments can provide one or more of the following benefits. Various embodiments can avoid data transfer latency between individual programming operations (individual programming cycles) for each wordline of one or more blocks of a memory circuit die (where each wordline corresponds to one or more pages). Various embodiments can avoid command latency of issuing separate commands to perform individual programming operations (individual programming cycles) for each wordline of one or more blocks of a memory circuit die. Various embodiments can avoid polling each wordlines of one or more blocks of a memory circuit die. Various embodiments can skip one or more program verification operations (program verification cycles). Various embodiments can use parallel programming of multiple blocks, to reduce interactions between a host system (e.g., memory controller thereof) and a memory circuit die. Additionally, various embodiments can avoid program failure handling (e.g., exception handling) by ignoring the results of program verification operations (program verification cycles) or by skipping program verification operations (program verification cycles) between individual programming operations (individual programming cycles). Given that the padding data being programmed is generally non-meaningful data, and other manufacturing processes can be used to mark bad blocks of a memory die, the results can be safely ignored without detrimental consequences.

As used herein, a programming operation can refer to a program cycle that programs one or more memory cells of a block (e.g., memory cells of one or more wordline of the block) with data. A programming operation can comprise a program sequence that applies a series of voltages to one or more memory cells (e.g., of one or more wordlines) of one or more blocks of a memory circuit die. As used herein, a program verification operation can refer to a program verification cycle (or verification cycle) performed after a programming operation to determine whether the programming operation programmed one or more memory cells of a block correctly.

As used herein, padding data can comprise random data, filler data, pattern data (e.g., generated by a data pattern process), garbage data, “don't care” data, or other non-meaningful data. As used herein, writing padding data to one or more blocks can also be referred to as padding (or performing a padding operation on) the one or more blocks (with padding data).

Disclosed herein are some examples of low-latency loading of padding data onto blocks of a memory circuit die, as described herein.

FIG. 1 illustrates an example computing system 100 that includes a memory sub-system 110, in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, a secure digital (SD) card, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-systems 110. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, and the like.

The host system 120 can include a processor chipset and a software stack executed by the processor chipset. The processor chipset can include one or more cores, one or more caches, a memory controller (e.g., NVDIMM controller), and a storage protocol controller (e.g., a peripheral component interconnect express (PCIe) controller, serial advanced technology attachment (SATA) controller). The host system 120 uses the memory sub-system 110, for example, to write data to the memory sub-system 110 and read data from the memory sub-system 110.

The host system 120 can include or be coupled to the memory sub-system 110 so that the host system 120 can read data from or write data to the memory sub-system 110. The host system 120 can be coupled to the memory sub-system 110 via a physical host interface. Examples of a physical host interface include, but are not limited to, a serial advanced technology attachment (SATA) interface, a peripheral component interconnect express (PCIe) interface, a compute express link (CXL) interface, a universal serial bus (USB) interface, a Fibre Channel interface, a Serial Attached SCSI (SAS) interface, etc. The physical host interface can be used to transmit data between the host system 120 and the memory sub-system 110. The host system 120 can further utilize an NVM Express (NVMe) interface to access the memory devices 130, 140 when the memory sub-system 110 is coupled with the host system 120 by the PCIe or CXL interface. The physical host interface can provide an interface for passing control, address, data, and other signals between the memory sub-system 110 and the host system 120.

FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random-access memory (DRAM) and synchronous dynamic random-access memory (SDRAM).

Some examples of non-volatile memory devices (e.g., memory device 130) include a NAND-type flash memory and write-in-place memory, such as a three-dimensional (3D) cross-point memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND-type flash memory includes, for example, two-dimensional (2D) NAND and 3D NAND.

Each of the memory devices 130 can include one or more arrays of memory cells. One type of memory cell, for example, SLCs, can store one bit per cell. Other types of memory cells, such as MLCs, TLCs, QLCs, and penta-level cells (PLCs), can store multiple or fractional bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, or a QLC portion of memory cells. The memory cells of the memory devices 130 can be grouped as pages that can refer to a logical unit of the memory device used to store data. With some types of memory (e.g., NAND), pages can be grouped to form blocks. As used herein, a block comprising SLCs can be referred to as an SLC block, a block comprising MLCs can be referred to as an MLC block, a block comprising TLCs can be referred to as a TLC block, and a block comprising QLCs can be referred to as a QLC block.

Although non-volatile memory components such as NAND-type flash memory (e.g., 2D NAND, 3D NAND) and 3D cross-point array of non-volatile memory cells are described, the memory device 130 can be based on any other type of non-volatile memory, such as read-only memory (ROM), phase change memory (PCM), self-selecting memory, other chalcogenide-based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide-based RRAM (OxRAM), negative-or (NOR) flash memory, and electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or another suitable processor.

The memory sub-system controller 115 can include a processor (processing device) 117 configured to execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, and so forth. The local memory 119 can also include ROM for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands, requests, or operations from the host system 120 and can convert the commands, requests, or operations into instructions or appropriate commands to achieve the desired access to the memory devices 130 and/or the memory device 140. The memory sub-system controller 115 can be responsible for other operations such as wear leveling operations, garbage collection operations, error detection and ECC operations, encryption operations, caching operations, and address translations between a logical address (e.g., LBA, namespace) and a physical memory address (e.g., physical block address) that are associated with the memory devices 130. The memory sub-system controller 115 can further include host interface circuitry to communicate with the host system 120 via the physical host interface. The host interface circuitry can convert the commands received from the host system 120 into command instructions to access the memory devices 130 and/or the memory device 140 as well as convert responses associated with the memory devices 130 and/or the memory device 140 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, a memory device 130 is a managed memory device, which is a raw memory device combined with a local controller (e.g., local media controller 135) for media management within the same memory device package. An example of a managed memory device is a managed NAND (MNAND) device.

Each of the memory devices 130, 140 includes a memory die 150, 160. For some embodiments, each of the memory devices 130, 140 represents a memory device that comprises a printed circuit board, upon which its respective memory die 150, 160 is solder mounted.

The memory sub-system controller 115 includes a low-latency padding data writer 113 that enables or facilitates the memory sub-system controller 115 to load (e.g., write) padding data onto blocks of a memory die 162 as described herein. As shown, the memory die 162 comprises a data buffer component 164, which can temporarily store data being exchanged between one or more blocks of the memory die 162 and an entity external to the memory die 162, such as the memory sub-system controller 115 or the host system 120 depending on the embodiment. Depending on the embodiment, the data buffer component 164 comprises a set of latches (e.g., primary, secondary, tertiary latches), cache memory (e.g., PDC, SDC), or a local memory of a memory circuit die. For some embodiments, the memory die 162 represents a memory circuit die prior to the memory circuit die being assembled into a memory device (e.g., by being solder mounted to a printed circuit board). Additionally, for some embodiments, the memory sub-system 110 represents a hardware system (e.g., workbench or test bench) used by a manufacturer as part of manufacturing a memory device (e.g., 130, 140) or manufacturing the memory die 162. For instance, the manufacturer can operatively couple the memory die 162 to the memory sub-system 110 and use the memory sub-system 110 to load padding data onto blocks of the memory die 162 prior to the memory die 162 being mounted (e.g., solder mounted) to a printed circuit board to form a memory device (e.g., 130, 140). For alternative embodiments, the memory die 162 can be operatively coupled to the host system 120 (e.g., which includes a memory controller and local memory), and the loading of the padding data onto blocks of the memory die 162 can be directly facilitated by the host system 120.

An embodiment can implement an approach (e.g., host or host controller firmware approach) where a host system, or a memory controller thereof, primarily facilitates loading of padding data onto one or more blocks of a memory circuit die. For example, the host system 120 (or a memory controller thereof) can load, into the data buffer component 164 (e.g., set of latches, PDC, SDC, local memory) of the memory die 162, padding data (e.g., comprising data pattern) to be programmed onto one or more blocks of the memory die 162. The host system 120 (or the memory controller thereof) can trigger a programming operation (e.g., programming sequence) on a wordline N (corresponding to one or more pages) of one or more blocks of the memory die 162. After the wordline N is programmed, the data buffer component 164 of the memory die 162 can retain the padding data, used for the last programming operation (regardless of whether the last programming operation is successful or unsuccessful), for a next programming operation on another wordline of the one or more blocks of the memory die 162. Accordingly, the host system 120 (or the memory controller thereof) can trigger a programming operation on a wordline N+1 of one or more blocks of the memory die 162. This can continue/be repeated until a specified wordline (e.g., wordline N+K) of one or more blocks of the memory die 162 is programmed. During this process, where supported by the memory die 162, the host system 120 (or the memory controller thereof) can skip a program verification operation (program verification cycle) between one or more programming operations. For some embodiments, where a host system (or a memory controller thereof) primarily facilitates loading of padding data onto one or more blocks of a memory circuit die, the host system (or the memory controller thereof) uses existing commands (e.g., existing command sequences) in the set of commands to facilitate the loading of padding data onto blocks of the memory circuit die as described herein.

Alternatively, an embodiment can implement an approach (e.g., memory circuit die firmware approach) where a memory circuit die primarily facilitates loading of padding data onto one or more blocks of a memory circuit die. For example, the host system 120 (or a memory controller thereof) can use a set of commands (e.g., command sequence) to trigger the loading of padding data (e.g., comprising data pattern) on local memory of the host system 120 (or a memory controller thereof) and loading (e.g., transferring) the padding data from that local memory to the data buffer component 164 of the memory die 162. The memory die 162 can receive one or more of the set of commands from the host system 120 (or a memory controller thereof) and, based on the one or more received commands, the memory die 162 can one or more wordlines (each corresponding to one or more pages) of one or more blocks of the memory die 162 to be programmed using the padding data stored in the data buffer component 164. The memory die 162 can perform a programming operation wordline-by-wordline with some portion of the padding data stored (and retained) in the data buffer component 164, can do so starting from a specified location (e.g., wordline specified by at least one of the received commands from the host system 120), and can do so until a specified number of wordlines (e.g., wordline specified by at least one of the received commands from the host system 120) have been programmed with some portion of the padding data stored (and retained) in the data buffer component 164. The memory die 162 can perform plurality of individual (e.g., single) programming operations on individual (e.g., single) wordlines of one or more blocks of the memory die 162 using some portion of the padding data stored (and retained) in the data buffer component 164, or the memory die 162 can perform a set of batch programming operations, with each batch programming operation causing programming of multiple wordlines of one or more blocks of the memory die 162 in parallel using some portion of the padding data stored (and retained) in the data buffer component 164. Additionally, the memory die 162 can skip a program verification operation between one or more programming operations, and can do so by way of an SLC-block programming operation. The memory die 162 can set the memory die 162 to a busy state while padding data load process is being performed, and can set the memory die 162 to a non-busy state (e.g., ready state) after padding data load process is completed. For some embodiments, where a memory circuit die primarily facilitates loading of padding data onto one or more blocks of a memory circuit die, the memory circuit die (e.g., a controller thereof) supports one or more new commands (e.g., command sequences) to facilitate the loading of padding data onto blocks of the memory circuit die as described herein.

Various embodiments are described herein with respect to a padding data load process being performed with respect to a memory die (e.g., 162) prior to the memory die being assembled into a larger system or device (e.g., solder mounted onto a printed circuit board). However, for some embodiments, a padding data load process described herein can be performed with respect to a memory die (e.g., 150, 160) of a memory device (e.g., 130, 140) after the memory device has been manufactured to include the memory die, and further after the memory device has been assembled into a memory sub-system (e.g., 110). As described herein, padding data stored on a memory die (of a memory device) can mitigate the thermal impact of a supply chain on one or more blocks of the memory die.

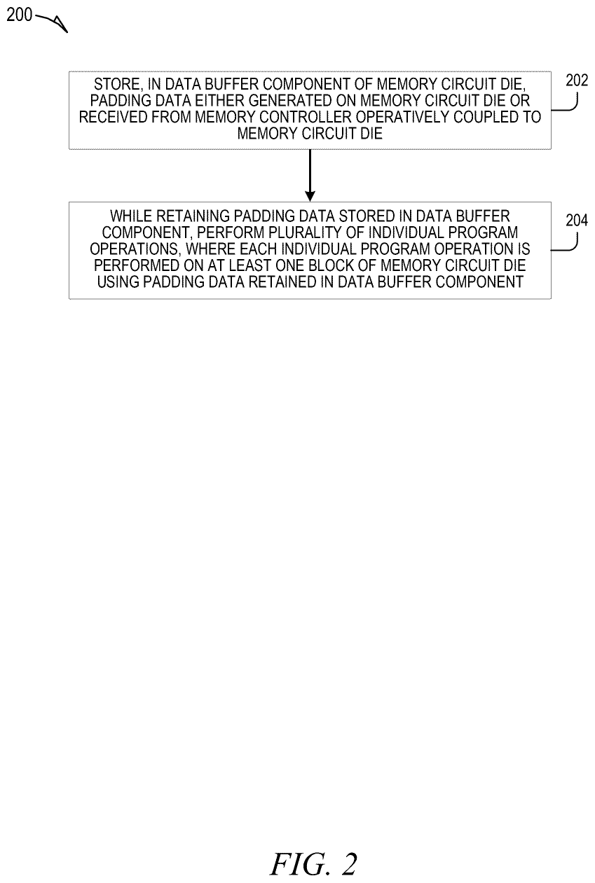

FIGS. 2 through 4 illustrate flow diagrams of example methods 200, 300, 400 for low-latency loading of padding data onto blocks of a memory circuit die, in accordance with some embodiments of the present disclosure. Any of methods 200, 300, 400 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, any of methods 200, 300, 400 is performed by the memory sub-system controller 115 of FIG. 1 based on the low-latency padding data writer 113. Additionally, or alternatively, for some embodiments, any of methods 200, 300, 400 is performed, at least in part, by the local media controller 135 of the memory device 130 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are used in every embodiment. Other process flows are possible.

Referring now to method 200 of FIG. 2, method 200 represents an example method having operations performed by a memory circuit die. Depending on the embodiment, a memory circuit die can perform method 200 in response to two or more commands (e.g., sequence of commands) received from a memory controller (e.g., the memory sub-system controller 115 of the memory sub-system 110, or a memory controller of the host system 120) operatively coupled to the memory circuit die.

At operation 202, a memory circuit die (e.g., 162) stores, in a data buffer component (e.g., 164) of the memory circuit die, padding data that is either generated on the memory circuit die, or that is received from a memory controller (e.g., the memory sub-system controller 115 of the memory sub-system 110, or a memory controller of the host system 120) operatively coupled to the memory circuit die. For some embodiments, the memory circuit die comprises a plurality of blocks, where each block comprises a plurality of wordlines. Depending on the type of block, each wordline of a given block can correspond to one or more pages of the given block.

During operation 204, while retaining the padding data stored in the data buffer component (e.g., 164), the memory circuit die (e.g., 162) performs a plurality of individual program operations, where each individual program operation (of the plurality) is performed on at least one wordline of the plurality of blocks of the memory circuit die using at least a portion of the padding data retained in the data buffer component. According to some embodiments, the padding data is stored and retained in between different individual programming operations of the plurality of individual program operations. For some embodiments, operation 204 comprises performing an individual program operation for each wordline (e.g., wordline-by-wordline) of each block of the plurality of blocks using at least a portion of the padding data retained in the data buffer component, where the plurality of individual program operations is performed while retaining the padding data in the data buffer component between performance of individual program operations of a plurality of individual program operations. For some embodiments, operation 204 comprises performing a set of batch programming operations on two or more wordlines of the plurality of blocks using at least a portion of the padding data retained in the data buffer component, where each batch programming operation comprises programming two or more blocks in parallel (e.g., blocks on the same plane or on the same logical unit number (LUN)) using at least a portion of the padding data retained in the data buffer component. For some embodiments, operation 204 comprises performing the plurality of individual program operations on the memory circuit die while skipping a program verification operation at least once between performance of individual program operations of the plurality of individual program operations. For example, the set of commands can include a command that causes the memory circuit die to skip the program verification operation after an individual programming operation For instance, the set of commands can include a single command having a setting (e.g., trim setting) that causes the memory circuit die to perform a programming operation on a single wordline and skip a program verification operation after the programming operation. Alternatively, operation 204 can comprise ignoring a result of a program verification operation (e.g., ignore program failure). The memory circuit die (e.g., 162) can set the memory circuit die to a busy state during operation 204, and the memory circuit die can set the memory circuit die to a non-busy state (e.g., ready state) at the end of operation 204.

According to some embodiments, the data buffer component (e.g., 164) of the memory circuit die (e.g., 162) comprises a set of latches, where the set of latches comprises a set of primary latches, and where each primary latch is configured to store a single page of data. For some embodiments, each program operation of the plurality of individual program operations is a single-level cell (SLC) block program operation (e.g., that uses padding data stored in the set of primary latches), while each block of the plurality of blocks is a triple-level cell (TLC) block. Additionally, for some embodiments, each program operation of the plurality of individual program operations is a single-level cell (SLC) block program operation (e.g., that uses padding data stored in the set of primary latches), while each block of the plurality of blocks is a quad-level cell (QLC) block. As described herein, use of an SLC block program operation for each individual programming operation can facilitate skipping of a program verification operation between individual program operations.

According to some embodiments, the data buffer component (e.g., 164) of the memory circuit die (e.g., 162) comprises a set of latches, where the set of latches comprises a set of primary latches and a set of secondary latches, where each primary latch is configured to store a single page of data, and where each secondary latch is configured to store at least two pages of data. For some embodiments, each program operation of the plurality of individual program operations is a triple-level cell (TLC) block program operation (e.g., that uses padding data stored in the set of primary latches and the set of secondary latches), where each block of the plurality of blocks is a triple-level cell (TLC) block. Additionally, for some embodiments, each program operation of the plurality of individual program operations is a triple-level cell (TLC) block program operation (e.g., that uses padding data stored in the set of primary latches and the set of secondary latches), while each block of the plurality of blocks is a quad-level cell (QLC) block.

According to some embodiments, the data buffer component (e.g., 164) of the memory circuit die (e.g., 162) comprises a set of latches, where the set of latches comprises a set of primary latches, a set of secondary latches, and a set of tertiary latches, where each primary latch is configured to store a single page of data, where each secondary latch is configured to store at least two pages of data, and where each tertiary latch is configured to at least a single page of data. For some embodiments, each program operation of the plurality of individual program operations is a quad-level cell (QLC) block program operation (e.g., that uses padding data stored in the set of primary latches, the set of secondary latches, and the set of tertiary latches), where each block of the plurality of blocks is a quad-level cell (QLC) block.

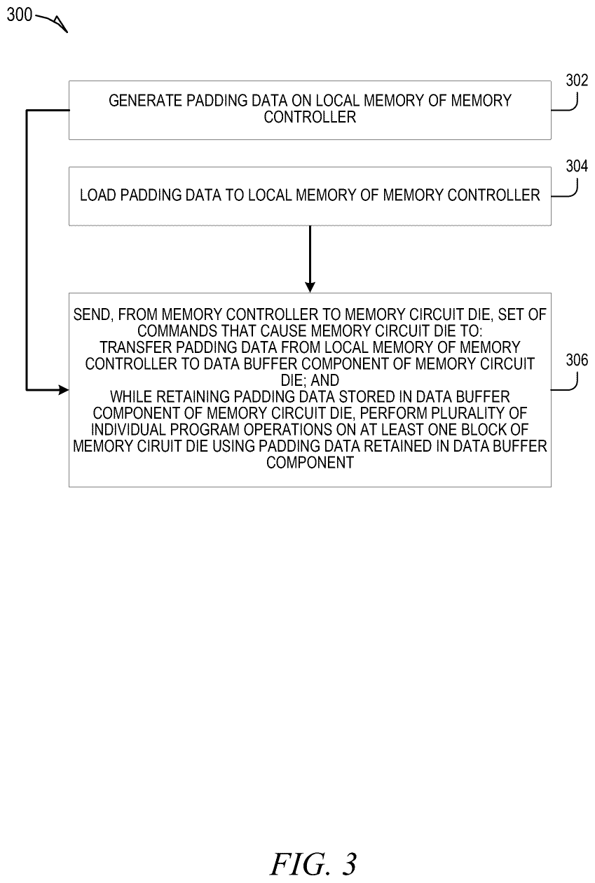

Referring now to method 300 of FIG. 3, method 300 represents an example method having operations performed by a memory controller, such as a memory sub-system controller (e.g., 115) of a memory sub-system (e.g., 110), or a memory controller of a host system (e.g., 120). Depending on the embodiment, a memory controller can perform method 300 during a manufacturing process (e.g., of a memory circuit die or a memory device), or after a manufacturing process but prior to shipping of the memory circuit die (e.g., prior to transportation of the memory circuit die through a memory circuit die or memory device supply chain).

At operation 302, a memory controller (e.g., the memory sub-system controller 115, or a memory controller of the host system 120) generates padding data on local memory that is operatively coupled to or part of the memory controller. Alternatively, at operation 304, the memory controller loads (e.g., from a secondary data storage device) the padding data to local memory that is operatively coupled to or part of the memory controller (e.g., where the padding data was previously generated and then stored on the secondary data storage device).

From operation 302 or operation 304, method 300 proceeds to operation 306. At operation 306, the memory controller (e.g., the memory sub-system controller 115, or a memory controller of the host system 120) sends, to a memory circuit die (e.g., 162), a set of commands (e.g., issuing a sequence of commands) that cause the memory circuit die to perform operations for loading padding data to one or more blocks of the memory circuit die. For some embodiments, the set of commands causes the memory circuit die (e.g., 162) to transfer (e.g., send) the padding data from the local memory of the memory controller to a data buffer component (e.g., 164) of the memory circuit die. For instance, the set of commands can include one or more individual commands to cause the memory circuit die (e.g., 162) to transfer the padding data from the memory controller to the data buffer component (e.g., 164) of the memory circuit die. Additionally, for some embodiments, the set of commands causes the memory circuit die (e.g., 162) to perform a plurality of individual program operations on the memory circuit die while retaining the padding data stored in the data buffer component (e.g., 164), where each individual program operation is performed on at least one wordline of the plurality of blocks using at least a portion of the padding data retained in the data buffer component. For instance, the set of commands can include, for each wordline to be programmed with at least a portion of the padding data, an individual command that causes the memory circuit die to perform a single programming operation on a single wordline of a block of the memory circuit die. Depending on the embodiment, the set of commands can comprise at least one command that specifies a start location (e.g., start wordline) of the memory circuit die for loading padding data, and can comprise at least one command that specifies a number of wordlines (e.g., starting from a first wordline) on which padding data is to be loaded. According to some embodiments, operation 306 is similar to operation 204 of method 200.

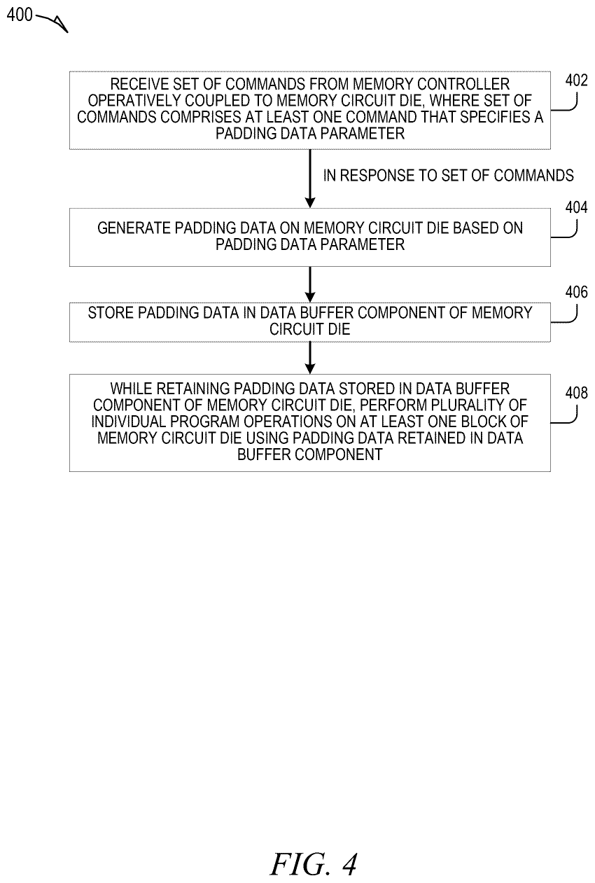

Referring now to method 400 of FIG. 4, method 400 represents an example method having operations performed by a memory circuit die (e.g., 162). At operation 402, the memory circuit die (e.g., 162) receives a set of commands from a memory controller (e.g., the memory sub-system controller 115 of the memory sub-system 110, or a memory controller of the host system 120) operatively coupled to the memory circuit die, where the set of commands comprises at least one command that specifies a padding data parameter. Depending on the embodiment, the set of commands can comprise at least one command that specifies a start location (e.g., start wordline) of the memory circuit die for loading padding data, and can comprise at least one command that specifies a number of wordlines (e.g., starting from a first wordline) on which padding data is to be loaded.

In response to the set of commands received from the memory controller, at operation 404, the memory circuit die (e.g., 162) generates padding data on the memory circuit die based on the padding data parameter. Depending on the embodiment, the padding data parameter can identify content for the padding data. For instance, the padding data parameter can identify a predetermined content for the padding data, or can identify a data pattern that is to be repeated (e.g., a data multiplication feature of the memory circuit die) within the content of the padding data to form the padding data. At operation 406, the memory circuit die (e.g., 162) stores the padding data generated by operation 404 in a data buffer component (e.g., 164) of the memory circuit die (e.g., 162).

During operation 408, the memory circuit die (e.g., 162) performs a plurality of individual program operations on the memory circuit die while retaining the padding data stored in the data buffer component (e.g., 164), where each individual program operation is performed on at least one wordline of the plurality of blocks using at least a portion of the padding data retained in the data buffer component. According to some embodiments, operation 408 is similar to operation 204 of method 200.

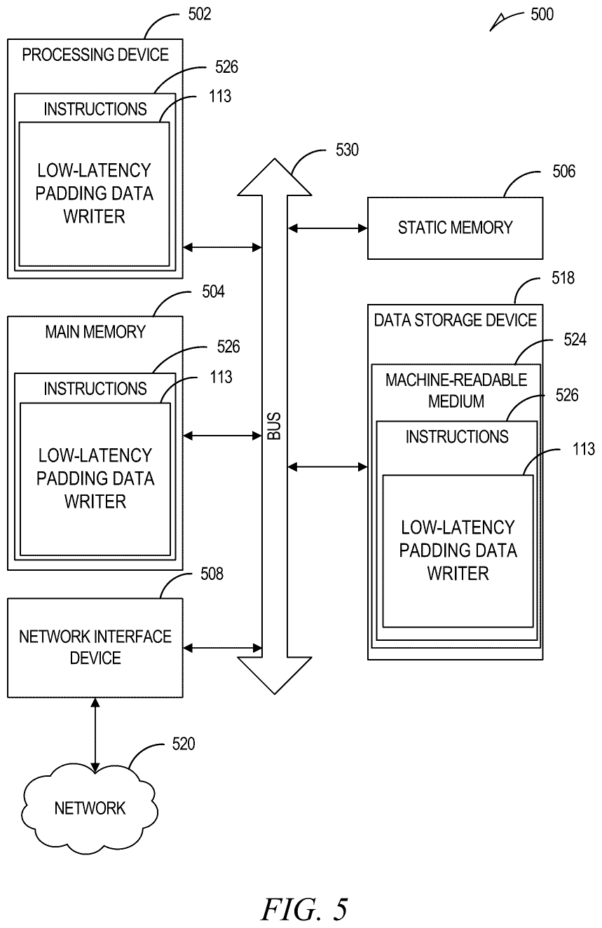

FIG. 5 illustrates an example machine in the form of a computer system 500 within which a set of instructions can be executed to cause the machine to perform any one or more of the methodologies discussed herein. In some embodiments, the computer system 500 can correspond to a host system (e.g., the host system 120 of FIG. 1) that includes, is coupled to, or utilizes a memory sub-system (e.g., the memory sub-system 110 of FIG. 1) or can be used to perform the operations described herein. In alternative embodiments, the machine can be connected (e.g., networked) to other machines in a local area network (LAN), an intranet, an extranet, and/or the Internet. The machine can operate in the capacity of a server or a client machine in a client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 500 includes a processing device 502, a main memory 504 (e.g., ROM, flash memory, DRAM such as SDRAM or Rambus DRAM (RDRAM), etc.), a static memory 506 (e.g., flash memory, static random access memory (SRAM), etc.), and a data storage device 518, which communicate with each other via a bus 530.

The processing device 502 represents one or more general-purpose processing devices such as a microprocessor, a central processing unit, or the like. More particularly, the processing device 502 can be a complex instruction set computing (CISC) microprocessor, a reduced instruction set computing (RISC) microprocessor, a very long instruction word (VLIW) microprocessor, a processor implementing other instruction sets, or processors implementing a combination of instruction sets. The processing device 502 can also be one or more special-purpose processing devices, such as an application-specific integrated circuit (ASIC), a field programmable gate array (FPGA), a digital signal processor (DSP), a network processor, or the like. The processing device 502 is configured to execute instructions 526 for performing the operations and steps discussed herein. The computer system 500 can further include a network interface device 508 to communicate over a network 520.

The data storage device 518 can include a machine-readable storage medium 524 (also known as a computer-readable medium) on which is stored one or more sets of instructions 526 or software embodying any one or more of the methodologies or functions described herein. For some embodiments, the machine-readable storage medium 524 is a non-transitory machine-readable storage medium. The instructions 526 can also reside, completely or at least partially, within the main memory 504 and/or within the processing device 502 during execution thereof by the computer system 500, the main memory 504 and the processing device 502 also constituting machine-readable storage media. The machine-readable storage medium 524, data storage device 518, and/or main memory 504 can correspond to the memory sub-system 110 of FIG. 1.

In one embodiment, the instructions 526 include instructions to implement functionality corresponding to loading padding data onto blocks of a memory circuit die as described herein (e.g., the low-latency padding data writer 113 of FIG. 1). While the machine-readable storage medium 524 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

In view of the above-described implementations of subject matter this application discloses the following list of examples, wherein one feature of an example in isolation or more than one feature of an example, taken in combination and, optionally, in combination with one or more features of one or more further examples are further examples also falling within the disclosure of this application.

Example 1 is a system comprising: a memory controller; and a memory circuit die operatively coupled to the memory controller and being external to the memory controller, the memory circuit die comprising: a plurality of blocks, each block comprising a plurality of wordlines; and a data buffer component configured to temporarily store data being exchanged between one or more wordlines of the plurality of blocks, the memory controller comprising: a local memory; and a processing device operatively coupled to the local memory, the processing device being configured to perform operations comprising: generating padding data on the local memory or loading the padding data to the local memory; and sending, to the memory circuit die, a set of commands that cause the memory circuit die to: transfer the padding data from the local memory of the memory controller to the data buffer component of the memory circuit die; and while retaining the padding data stored in the data buffer component, perform a plurality of individual program operations on the memory circuit die, each individual program operation being performed on at least one wordline of the plurality of blocks using at least a portion of the padding data retained in the data buffer component.

In Example 2, the subject matter of Example 1 includes, wherein the memory circuit die performs the plurality of individual program operations on the memory circuit die by performing an individual program operation for each wordline of each block of the plurality of blocks using at least a portion of the padding data retained in the data buffer component, and wherein the plurality of individual program operations is performed while retaining the padding data in the data buffer component between performance of individual program operations of a plurality of individual program operations.

In Example 3, the subject matter of Examples 1-2 includes, wherein the memory circuit die performs the plurality of individual program operations on the memory circuit die by performing a set of batch programming operations on two or more wordlines of the plurality of blocks using at least a portion of the padding data retained in the data buffer component, and wherein each batch programming operation comprises programming two or more blocks in parallel using at least a portion of the padding data retained in the data buffer component.

In Example 4, the subject matter of Examples 1-3 includes, wherein the memory circuit die performs the plurality of individual program operations on the memory circuit die while ignoring any errors detected by a program verification operation performed between performance of individual program operations of the plurality of individual program operations.

In Example 5, the subject matter of Examples 1˜4 includes, wherein the memory circuit die performs the plurality of individual program operations on the memory circuit die while skipping a program verification operations at least once between performance of individual program operations of the plurality of individual program operations.

In Example 6, the subject matter of Example 5 includes, wherein at least one program operation of the plurality of individual program operations comprises a single-level cell (SLC) block program operation.

In Example 7, the subject matter of Examples 1-6 includes, wherein the memory circuit die is set to a busy state while the plurality of individual program operations is performed.

In Example 8, the subject matter of Example 7 includes, wherein the memory circuit die is set to a non-busy state after the plurality of individual program operations has been performed.

In Example 9, the subject matter of Examples 1-8 includes, wherein the data buffer component comprises a set of latches.

In Example 10, the subject matter of Example 9 includes, wherein the set of latches comprises a set of primary latches, and wherein each primary latch is configured to store a single page of data.

In Example 11, the subject matter of Example 10 includes, wherein each program operation of the plurality of individual program operations is a single-level cell (SLC) block program operation, and wherein each block of the plurality of blocks is a triple-level cell (TLC) block.

In Example 12, the subject matter of Examples 10-11 includes, wherein each program operation of the plurality of individual program operations is a single-level cell (SLC) block program operation, and wherein each block of the plurality of blocks is a quad-level cell (QLC) block.

In Example 13, the subject matter of Examples 10-12 includes, wherein the set of latches comprises a set of secondary latches, and wherein each secondary latch is configured to store at least two pages of data.

In Example 14, the subject matter of Example 13 includes, wherein each program operation of the plurality of individual program operations is a triple-level cell (TLC) block program operation, and wherein each block of the plurality of blocks is a triple-level cell (TLC) block.

In Example 15, the subject matter of Examples 13-14 includes, wherein each program operation of the plurality of individual program operations is a triple-level cell (TLC) block program operation, and wherein each block of the plurality of blocks is a quad-level cell (QLC) block.

In Example 16, the subject matter of Examples 13-15 includes, wherein the set of latches comprises a set of tertiary latches, wherein each tertiary latch is configured to at least a single page of data, wherein each program operation of the plurality of individual program operations is a quad-level cell (QLC) block program operation, and wherein each block of the plurality of blocks is a quad-level cell (QLC) block.

Example 17 is at least one machine-readable medium including instructions that, when executed by a processing device of a memory sub-system, cause the processing device to perform operations to implement of any of Examples 1-16.

Example 18 is a method to implement of any of Examples 1-16.

Example 19 is a memory circuit die comprising: a plurality of blocks, each block comprising a plurality of wordlines; and a data buffer component configured to temporarily store data being exchanged between one or more wordlines of the plurality of blocks, the memory circuit die being configured to perform operations comprising: receiving a set of commands from a memory controller operatively coupled to the memory circuit die, the set of commands comprising at least one command that specifies a padding data parameter; and in response to the set of commands: generating padding data on the memory circuit die based on the padding data parameter; storing the padding data in the data buffer component; and while retaining the padding data stored in the data buffer component, performing a plurality of individual program operations on the memory circuit die, each individual program operation being performed on at least one wordline of the plurality of blocks using at least a portion of the padding data retained in the data buffer component.

Example 20 is a method comprising: storing, in a data buffer component of a memory circuit die, padding data either generated on the memory circuit die or received from a memory controller operatively coupled to the memory circuit die, the memory circuit die comprises a plurality of blocks, each block comprising a plurality of wordlines; and while retaining the padding data stored in the data buffer component, performing a plurality of individual program operations on the memory circuit die, each individual program operation being performed on at least one wordline of the plurality of blocks of the memory circuit die using at least a portion of the padding data retained in the data buffer component.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, which manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general-purpose computer selectively activated or reconfigured by a computer program stored in the computer. Such a computer program can be stored in a computer-readable storage medium, such as, but not limited to, any type of disk including floppy disks, optical disks, CD-ROMs, and magnetic-optical disks, ROMs, RAMs, EPROMS, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium (e.g., non-transitory machine-readable medium) having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a ROM, RAM, magnetic disk storage media, optical storage media, flash memory components, and so forth.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A system comprising:
a memory controller; and
a memory circuit die operatively coupled to the memory controller and being external to the memory controller, the memory circuit die comprising:
a plurality of blocks, each block comprising a plurality of wordlines; and
a data buffer component configured to temporarily store data being exchanged between one or more wordlines of the plurality of blocks,
the memory controller comprising:
a local memory; and
a processing device operatively coupled to the local memory, the processing device being configured to perform operations comprising:
generating padding data on the local memory or loading the padding data to the local memory; and
sending, to the memory circuit die, a set of commands that cause the memory circuit die to:
transfer the padding data from the local memory of the memory controller to the data buffer component of the memory circuit die; and
while retaining the padding data stored in the data buffer component, perform a plurality of individual program operations on the memory circuit die, each individual program operation being performed on at least one wordline of the plurality of blocks using at least a portion of the padding data retained in the data buffer component.

2. The system of claim 1, wherein the memory circuit die performs the plurality of individual program operations on the memory circuit die by performing an individual program operation for each wordline of each block of the plurality of blocks using at least a portion of the padding data retained in the data buffer component, and wherein the plurality of individual program operations is performed while retaining the padding data in the data buffer component between performance of individual program operations of a plurality of individual program operations.

3. The system of claim 1, wherein the memory circuit die performs the plurality of individual program operations on the memory circuit die by performing a set of batch programming operations on two or more wordlines of the plurality of blocks using at least a portion of the padding data retained in the data buffer component, and wherein each batch programming operation comprises programming two or more blocks in parallel using at least a portion of the padding data retained in the data buffer component.

4. The system of claim 1, wherein the memory circuit die performs the plurality of individual program operations on the memory circuit die while ignoring any errors detected by a program verification operation performed between performance of individual program operations of the plurality of individual program operations.

5. The system of claim 1, wherein the memory circuit die performs the plurality of individual program operations on the memory circuit die while skipping a program verification operations at least once between performance of individual program operations of the plurality of individual program operations.

6. The system of claim 5, wherein at least one program operation of the plurality of individual program operations comprises a single-level cell (SLC) block program operation.

7. The system of claim 1, wherein the memory circuit die is set to a busy state while the plurality of individual program operations is performed.

8. The system of claim 7, wherein the memory circuit die is set to a non-busy state after the plurality of individual program operations has been performed.

9. The system of claim 1, wherein the data buffer component comprises a set of latches.

10. The system of claim 9, wherein the set of latches comprises a set of primary latches, and wherein each primary latch is configured to store a single page of data.

11. The system of claim 10, wherein each program operation of the plurality of individual program operations is a single-level cell (SLC) block program operation, and wherein each block of the plurality of blocks is a triple-level cell (TLC) block.

12. The system of claim 10, wherein each program operation of the plurality of individual program operations is a single-level cell (SLC) block program operation, and wherein each block of the plurality of blocks is a quad-level cell (QLC) block.

13. The system of claim 10, wherein the set of latches comprises a set of secondary latches, and wherein each secondary latch is configured to store at least two pages of data.

14. The system of claim 13, wherein each program operation of the plurality of individual program operations is a triple-level cell (TLC) block program operation, and wherein each block of the plurality of blocks is a triple-level cell (TLC) block.

15. The system of claim 13, wherein each program operation of the plurality of individual program operations is a triple-level cell (TLC) block program operation, and wherein each block of the plurality of blocks is a quad-level cell (QLC) block.

16. The system of claim 13, wherein the set of latches comprises a set of tertiary latches, wherein each tertiary latch is configured to at least a single page of data, wherein each program operation of the plurality of individual program operations is a quad-level cell (QLC) block program operation, and wherein each block of the plurality of blocks is a quad-level cell (QLC) block.

17. A memory circuit die comprising:
a plurality of blocks, each block comprising a plurality of wordlines; and
a data buffer component configured to temporarily store data being exchanged between one or more wordlines of the plurality of blocks, the memory circuit die being configured to perform operations comprising:
receiving a set of commands from a memory controller operatively coupled to the memory circuit die, the set of commands comprising at least one command that specifies a padding data parameter; and
in response to the set of commands:
generating padding data on the memory circuit die based on the padding data parameter;
storing the padding data in the data buffer component; and
while retaining the padding data stored in the data buffer component, performing a plurality of individual program operations on the memory circuit die, each individual program operation being performed on at least one wordline of the plurality of blocks using at least a portion of the padding data retained in the data buffer component.

18. The memory circuit die of claim 17, wherein the plurality of individual program operations is performed on the at least one wordline using at least a portion of the padding data retained in the data buffer component while ignoring any errors detected by a program verification operation performed between performance of individual program operations of the plurality of individual program operations.

19. The memory circuit die of claim 17, wherein the plurality of individual program operations is performed on the at least one wordline using at least a portion of the padding data retained in the data buffer component while skipping one or more program verification operations at least once between performance of individual program operations of the plurality of individual program operations.

20. A method comprising:
storing, in a data buffer component of a memory circuit die, padding data either generated on the memory circuit die or received from a memory controller operatively coupled to the memory circuit die, the memory circuit die comprises a plurality of blocks, each block comprising a plurality of wordlines; and
while retaining the padding data stored in the data buffer component, performing a plurality of individual program operations on the memory circuit die, each individual program operation being performed on at least one wordline of the plurality of blocks of the memory circuit die using at least a portion of the padding data retained in the data buffer component.
